(19) United States
(12) Patent Application Publication
(10) Pub. No.: US 2026/0123436 A1
(43) Pub. Date: Apr. 30, 2026

(54) SEMICONDUCTOR PACKAGE

(71) Applicant: Samsung Electronics Co., Ltd., Suwon-si (KR)

(72) Inventors: Dongkuk Lee, Suwon-si (KR); Seungduk Baek, Suwon-si (KR)

(21) Appl. No.: 19/374,524

(22) Filed: Oct. 30, 2025

(30) Foreign Application Priority Data
Oct. 30, 2024 (KR) 10-2024-0151508

(51) Int. Cl. H01L 23/00; H01L 23/31; H01L 25/065

(52) U.S. Cl. CPC H10W 42/121; H10W 74/117; H10W 90/00

(57) ABSTRACT

A semiconductor package including a package substrate, a pair of first semiconductor chips mounted on the package substrate and facing each other in a first horizontal direction, a pair of second semiconductor chips respectively mounted on the pair of first semiconductor chips and facing each other in the first horizontal direction, a pair of molding members respectively disposed on the pair of first semiconductor chips, and covering peripheries of the pair of second semiconductor chips on the pair of first semiconductor chips, and an encapsulant covering peripheries of the pair of first semiconductor chips and some parts of the pair of molding members. A recess is formed in each of the pair of second semiconductor chips to a first depth in a direction in which the pair of second semiconductor chips face each other.

### CROSS-REFERENCE TO RELATED APPLICATION

This application is based on and claims priority under 35 U.S.C. § 119 to Korean Patent Application No. 10-2024-0151508, filed on Oct. 30, 2024, in the Korean Intellectual Property Office, the disclosure of which is incorporated by reference herein in its entirety.

### BACKGROUND

Aspects of the inventive concept relate to a semiconductor package, in particular, to a semiconductor package for effectively mounting semiconductor chips in a limited semiconductor package structure.

Recently, the electronic appliances market has seen a rapid increase in the demand for portable devices, and as such, the miniaturization and weight reduction of electronic components mounted on electronic appliances are in continuous demand. In order to implement miniaturized and lightweight electronic components, semiconductor package technology capable of integrating a plurality of individual devices into one package, as well as a technique of reducing the individual size of a mounted component, are necessary. In particular, in accordance with the need for high-performance and high-capacity semiconductors, the number of semiconductor chips mounted on semiconductor packages is increasing. However, due to a spatial limitation of the semiconductor package, a technique capable of improving spatial limitation by changing the method of arranging semiconductor chips is necessary.

### SUMMARY

Aspects of the inventive concept provide a semiconductor package capable of reducing a connection distance of a wiring for connecting signals between semiconductor chips while improving reliability of semiconductor chips mounted on a semiconductor package.

Aspects of the inventive concept also provides a semiconductor package capable of decreasing warpage of semiconductor chips while reducing a connection distance of a wiring for connecting signals between semiconductor chips.

It will be appreciated by one of ordinary skill in the art that that the objectives and effects that could be achieved with the disclosed aspects of the inventive concept are not limited to what has been particularly described above and other objectives will be more clearly understood from the following detailed description.

According to an embodiment, a semiconductor package includes a package substrate, a pair of first semiconductor chips mounted on the package substrate and facing each other in a first horizontal direction, a pair of second semiconductor chips respectively mounted on the pair of first semiconductor chips and facing each other in the first horizontal direction, a pair of molding members respectively disposed on the pair of first semiconductor chips, and covering peripheries of the pair of second semiconductor chips, and an encapsulant on the package substrate, the encapsulant covering peripheries of the pair of first semiconductor chips and some parts of the pair of molding members, wherein, in each of the pair of molding members, a first width in the horizontal direction in a first region where the pair of second semiconductor chips face each other is less than a second width in the horizontal direction in a second region where the pair of second semiconductor chips do not face each other, and wherein a recess is formed in each of the pair of second semiconductor chips to a first depth in a direction in which the pair of second semiconductor chips face each other.

According to an embodiment, a semiconductor package includes a package substrate, a pair of first semiconductor chips mounted on the package substrate and facing each other in a horizontal direction, a pair of second semiconductor chips mounted on the pair of first semiconductor chips and facing each other in the horizontal direction, a pair of molding members covering peripheries of the pair of second semiconductor chips on the pair of first semiconductor chips, and an encapsulant covering peripheries of the pair of first semiconductor chips and some parts of the pair of molding members, on the package substrate, wherein, in widths of each of the pair of molding members in the horizontal direction, a first width in a first region where the pair of second semiconductor chips face each other is less than a second width in a second region where the pair of second semiconductor chips do not face each other, a first recess of a first depth is formed in each of the pair of second semiconductor chips adjacent to the first region, and a second recess of a second depth that is less than the first depth is formed in each of the pair of second semiconductor chips adjacent to the second region.

According to an embodiment, a semiconductor package includes a package substrate, a pair of first semiconductor chips mounted on the package substrate and facing each other in a horizontal direction, a second semiconductor chip mounted on one of the pair of first semiconductor chips, a semiconductor chip stack mounted on the other first semiconductor chip of the pair of first semiconductor chips, a pair of molding members covering a periphery of the second semiconductor chip and a periphery of the semiconductor chip stack, on the pair of first semiconductor chips, and an encapsulant covering peripheries of the pair of first semiconductor chips and some parts of the pair of molding members, on the package substrate, the molding member arranged around the second semiconductor chip has a first width in the horizontal direction in a first region where the second semiconductor chip and the semiconductor chip stack face each other and a second width in the horizontal direction in a second region where the second semiconductor chip and the semiconductor chip stack do not face each other, the first width being less than the second width, and a groove of a first depth is formed in the second semiconductor chip in a direction in which the second semiconductor chip and the semiconductor chip stack face each other.

### BRIEF DESCRIPTION OF THE DRAWINGS

Embodiments will be more clearly understood from the following detailed description taken in conjunction with the accompanying drawings in which:

FIG. 1 is a cross-sectional view showing main components of a semiconductor package according to an embodiment;

FIGS. 2 to 6 are cross-sectional views showing main components of a semiconductor package according to an embodiment;

FIGS. 7 to 14 are cross-sectional views illustrating a method of manufacturing a semiconductor package according to an embodiment, according to a process order;

FIGS. 15 to 19 are plan views showing main components of a semiconductor package according to an embodiment; and

FIG. 20 is a block diagram schematically showing a semiconductor package according to some embodiments.

### DETAILED DESCRIPTION OF THE EMBODIMENTS

Hereinafter, one or more embodiments of the inventive concept will be described in detail with reference to accompanying drawings.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

Items described in the singular herein may be provided in plural, as can be seen, for example, in the drawings. Thus, the description of a single item (e.g., an upper electrode pad) that is provided in plural should be understood to be applicable to the remaining plurality of items unless context indicates otherwise. In addition, ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Spatially relative terms, such as “left,” “right,” “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly. In addition, a term that is referenced with a particular relative term may be described elsewhere with a different relative term.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

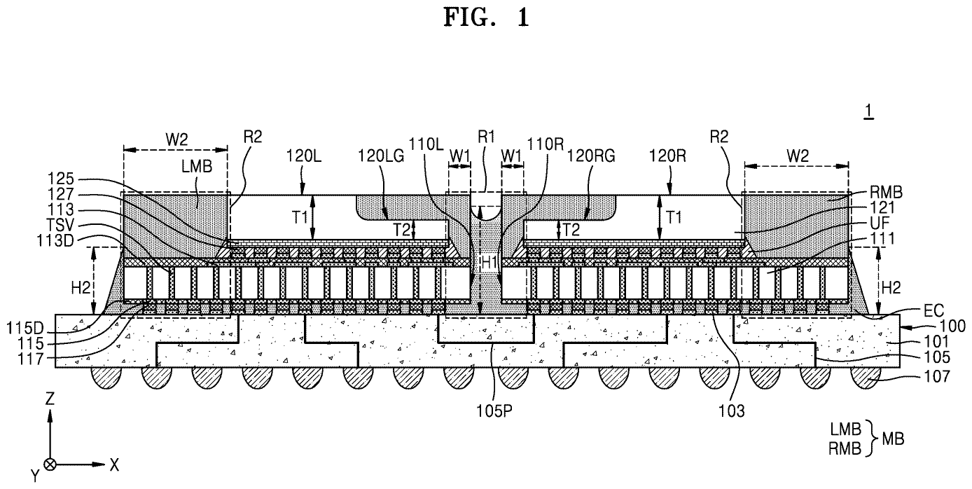

FIG. 1 is a cross-sectional view showing main components of a semiconductor package 1 according to an embodiment.

Referring to FIG. 1, the semiconductor package 1 includes a package substrate 100, a pair of first semiconductor chips 110R and 110L, a pair of second semiconductor chips 120R and 120L, an underfill UF, a molding member MB, and an encapsulant EC.

In a system in package in which a plurality of semiconductor chips are integrated as one package, the number of semiconductor chips constituting the semiconductor package 1 may vary depending on usage of the semiconductor package 1. For example, in the drawing, four semiconductor chips are mounted on the package substrate 100, but the number of semiconductor chips constituting the semiconductor package 1 is not limited thereto.

The package substrate 100 is a support substrate, and may include a body 101, a lower protective layer (not shown), and an upper protective layer (not shown). The package substrate 100 may be based on a printed circuit board (PCB), a wafer substrate, a ceramic substrate, a glass substrate, etc. In an embodiment, the package substrate 100 may be a PCB.

In the PCB, the body 101 is generally implemented by compressing a polymer material such as a thermosetting resin, an epoxy-based resin such as flame retardant 4 (FR-4), bismaleimide triazine (BT), Ajinomoto build up film (ABF), etc., or a phenol resin to a certain thickness to a film type, plating the film with copper foil on opposite surfaces, and forming a wiring that is a transfer path of an electrical signal through a patterning process.

The package substrate 100 may include a lower electrode pad (not shown) and an upper electrode pad 103. Also, a wiring layer 105 is formed on the package substrate 100, and the wiring layer 105 may be electrically connected to first and second semiconductor chips 110R, 110L, 120R, and 120L, which are connected to the upper electrode pad 103 on the upper surface of the package substrate 100. For example, the wiring layer 105 may be electrically connected to the first and second semiconductor chips 110R, 110L, 120R, and 120L through the upper electrode pad 103.

An external connection terminal 107 may be arranged on the lower electrode pad on the lower surface of the package substrate 100. The package substrate 100 may be electrically connected to a module substrate (not shown) or a system board (not shown) of an electronic appliance via the external connection terminal 107.

The pair of first semiconductor chips 110R and 110L may be mounted on the package substrate 100. The pair of first semiconductor chips 110R and 110L may be referred to as a first left semiconductor chip 110L and a first right semiconductor chip 110R according to the position in the drawing.

In some embodiments, the pair of first semiconductor chips 110R and 110L may further include a circuit region (not shown), and a buffer circuit capable of controlling capacitance loading may be formed in the circuit region. In some embodiments, at least one selected from a transistor, a diode, a capacitor, and a resistor may be included in the circuit region. In some embodiments, the pair of first semiconductor chips 110R and 110L may each be an interposer.

Each of the pair of first semiconductor chips 110R and 110L may include a base substrate 111, an upper redistribution layer 113 formed on an upper surface of the base substrate 111, and a lower redistribution layer 115 formed on a lower surface of the base substrate 111. An upper insulating layer 113D may be arranged around the upper redistribution layer 113, and a lower insulating layer 115D may be arranged around the lower redistribution layer 115.

The base substrate 111 may include a wafer including silicon (Si), e.g., crystalline silicon, polycrystalline silicon, or amorphous silicon. Each of the pair of first semiconductor chips 110R and 110L may include a plurality of through silicon vias (TSVs) passing through the base substrate 111.

The pair of first semiconductor chips 110R and 110L may be electrically connected to the package substrate 100 via a first internal connection terminal 117 located under the lower redistribution layer 115. Also, the package substrate 100 may include a connection wiring layer 105P, and the connection wiring layer 105P may provide electrical connection between the pair of first semiconductor chips 110R and 110L.

The pair of second semiconductor chips 120R and 120L may be mounted on the pair of first semiconductor chips 110R and 110L. The pair of second semiconductor chips 120R and 120L may be referred to as a second left semiconductor chip 120L and a second right semiconductor chip 120R according to the position thereof in the drawing. For example, the second left semiconductor chip 120L may be mounted on the first left semiconductor chip 110L, and the second right semiconductor chip 120R may be mounted on the first right semiconductor chip 110R.

In some embodiments, each of the pair of second semiconductor chips 120R and 120L may include a memory chip, for example, a volatile memory chip and/or a non-volatile memory chip. In some embodiments, each of the pair of second semiconductor chips 120R and 120L may include a logic device, for example, a central processor chip, a graphic processor chip, or an application processor. For example, the pair of second semiconductor chips 120R and 120L and the pair of first semiconductor chips 110R and 110L may perform different functions.

In some embodiments, a width of each of the pair of second semiconductor chips 120R and 120L in a first horizontal direction (X-direction) may be less than a width of each of the pair of first semiconductor chips 110R and 110L in the first horizontal direction (X-direction).

Each of the pair of second semiconductor chips 120R and 120L may include a base substrate 121, and a lower distribution layer 125 formed on a lower surface of the base substrate 121. The base substrate 121 may include a wafer including silicon (Si), e.g., crystalline silicon, polycrystalline silicon, or amorphous silicon.

In the semiconductor package 1 according to aspects of the inventive concept, the pair of second semiconductor chips 120R and 120L may further include a pair of grooves 120RG (e.g., “right groove”) and 120LG (e.g., “left groove”) in some parts of the base substrates 121 included therein. As illustrated in FIG. 1, for example, the pair of grooves 120RG may be formed as a cutout region or recess within the base substrate 121 of the pair of second semiconductor chips 120R and 120L. The second left semiconductor chip 120L may have the left groove 120LG in a part of the base substrate 121 included therein, and the second right semiconductor chip 120R may have the right groove 120RG in a part of the base substrate 121 included therein. This will be described later.

The pair of second semiconductor chips 120R and 120L may be electrically connected to the pair of first semiconductor chips 110R and 110L via second internal connection terminals 127 located under the lower distribution layers 125.

The underfill UF may be formed in a space between the first left semiconductor chip 110L and the second left semiconductor chip 120L and a space between the first right semiconductor chip 110R and the second right semiconductor chip 120R. For example, during a process of electrically connecting the pair of first semiconductor chips 110R and 110L and the pair of second semiconductor chips 120R and 120L, respectively, via the second internal connection terminal 127, the pair of first semiconductor chips 110R and 110L and the pair of second semiconductor chips 120R and 120L may have a gap therebetween. The gap may cause an issue in the connection reliability between the pair of first semiconductor chips 110R and 110L and the pair of second semiconductor chips 120R and 120L, and the underfill UF may be formed within the gap or a portion of the gap to reinforce the connection.

The molding member MB may be formed to surround the side surface (e.g., peripheries, sidewalls) of each of the pair of second semiconductor chips 120R and 120L. The molding member MB may include a pair of molding members. For example, the molding member MB may include a left molding member (e.g., a first molding member) LMB and a right molding member (e.g., a second molding member) RMB. The left molding member LMB may be formed to surround the side surface (e.g., peripheries, sidewalls) of the second left semiconductor chip 120L. The right molding member RMB may be formed to surround the side surface (e.g., peripheries, sidewalls) of the second right semiconductor chip 120R. However, unlike the drawing, upper surfaces of the pair of second semiconductor chips 120R and 120L may be covered by the molding member MB. The molding member MB may protect the pair of second semiconductor chips 120R and 120L against external influences such as contamination (e.g., humidity or gas), impact, etc.

The molding member MB may include, for example, an epoxy molding compound. The epoxy molding compound may have a Young's modulus of about 15 GPa to about 30 GPa, and a thermal expansion coefficient of about 3 ppm to about 30 ppm. The molding member MB is not limited to the epoxy molding compound, but may include various materials, e.g., an epoxy-based material, a thermosetting material, a thermoplastic material, an ultraviolet (UV)-processed material, etc. The thermosetting material may include a phenol type, acid anhydrate type, and amine type hardener and an additive of acryl polymer.

The encapsulant (e.g., encapsulation layer) EC may be formed on the package substrate 100 so as to cover peripheries (e.g., sidewalls) of the pair of first semiconductor chips 110R and 110L and a part of the molding member MB surrounding the pair of second semiconductor chips 120R and 120L.

The encapsulant EC may include a material that is substantially the same as or similar to that of the molding member MB and the underfill UF. For example, the encapsulant EC and the underfill UF may include the epoxy molding compound, but is not limited thereto.

The semiconductor package 1 according to aspects of the inventive concept may include the molding member MB of an asymmetric shape (e.g., asymmetric overhang) on opposite sidewalls of each of the pair of second semiconductor chips 120R and 120L. The underfill UF, the molding member MB, and the encapsulant EC may be formed separately as further detailed below.

Here, for convenience of description, a region where the pair of second semiconductor chips 120R and 120L face each other is referred to as a first region R1, and a region where the pair of second semiconductor chips 120R and 120L do not face each other is referred to as a second region R2.

Based on outermost sides of the second left semiconductor chip 120L, a width of the left molding member LMB in the first horizontal direction (X-direction) may be a first width W1 in the first region R1 and a second width W2 that is greater than the first width W1 in the second region R2. The first width W1 of the left molding member LMB may be measured from a first outermost side surface of the second left semiconductor chip 120L to a first outermost side surface of the left molding member LMB. The first outermost side surface of the second left semiconductor chip 120L may contact the left molding member LMB. The second width W2 of the left molding member LMB may be measured from a second outermost side surface of the second left semiconductor chip 120L to a second outermost side surface of the left molding member LMB. The second outermost side surface of the second left semiconductor chip 120L may contact the left molding member LMB.

Based on outermost sides of the second right semiconductor chip 120R, a width of the right molding member LMB in the first horizontal direction (X-direction) may be the first width W1 in the first region R1 and the second width W2 in the second region R2. The first width W1 of the right molding member RMB may be measured from a first outermost side surface of the second right semiconductor chip 120R to a first outermost side surface of the right molding member RMB. The first outermost side surface of the second right semiconductor chip 120R may contact the right molding member RMB. The second width W2 of the right molding member RMB may be measured from a second outermost side surface of the second right semiconductor chip 120R to a second outermost side surface of the right molding member RMB. The second outermost side surface of the right semiconductor chip 120R may contact the right molding member RMB. The first width W1 with respect to the left molding member LMB may be the same as the first width W1 with respect to the right molding member RMB. The second width W2 with respect to the left molding member LMB may be the same as the second width W2 with respect to the right molding member RMB.

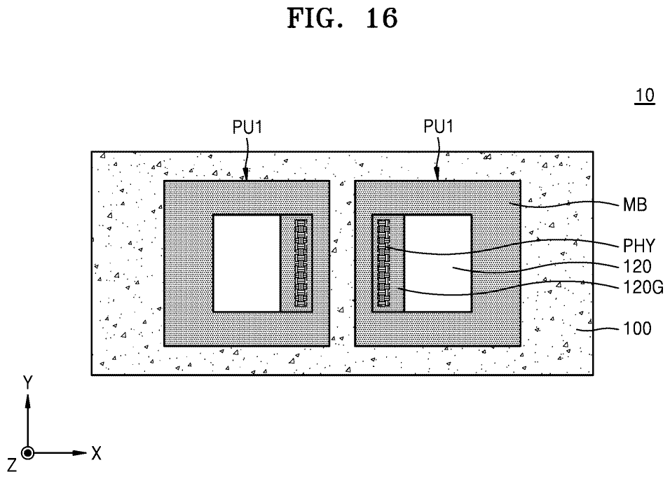

By forming the first width W1 of the molding member MB in the first horizontal direction (X-direction) in the first region R1 to be relatively short, the physical distance between the second left semiconductor chip 120L and the second right semiconductor chip 120R may be designed to be closer. This allows a pair of physical signal connection structure PHY (see FIG. 16) that transmit/receive signals between the second left semiconductor chip 120L and the second right semiconductor chip 120R to be reduced, and thus, the connection distance of the distribution for connecting signals may be effectively reduced.

Additionally, by forming the second width W2 of the molding member MB in the first horizontal direction (X-direction) in the second region R2 to be relatively long, reliability for protecting the second left semiconductor chip 120L and the second right semiconductor chip 120R against external influences may be improved.

Here, the pair of physical signal connection structures PHY (see FIG. 16) included in the pair of second semiconductor chips 120R and 120L may be electrically connected to each other via the pair of first semiconductor chips 110R and 110L and the package substrate 100. In addition, the pair of grooves 120RG and 120LG formed in the pair of second semiconductor chips 120R and 120L may be arranged to overlap the pair of physical signal connection structures PHY (see FIG. 16) in the vertical direction (Z-direction).

Also, the reliability of protecting the part of the molding member MB having a relatively small width in the first region R1 may be reinforced by the encapsulant EC. For example, a portion of the encapsulant EC may be formed in the first region R1 and the second region R2. The portion of the encapsulant EC formed in the first region R1 may contact a top surface of the package substrate 100 and a bottom surface of the lower insulating layer 115D. The portion of the encapsulant EC formed in the first region R1 may also contact side surfaces of the molding member MB (e.g., the first outermost side surface of the left molding member LMB and the first outermost side surface of the right molding member LMB) disposed in the first region R1 and facing side surfaces of the first and second semiconductor chips 110R and 110L. For example, the portion of the encapsulant EC formed in the first region R1 may contact the first outermost side surface of the left molding member LMB and the first outermost side surface of the right molding member RMB. The portion of the encapsulant EC formed in the second region R2 may contact a top surface of the package substrate 100 and a bottom surface of the lower insulating layer 115D. The portion of the encapsulant EC formed in the second region R2 may also contact side surfaces of the molding member MB disposed in the first region R2. For example, the portion of the encapsulant EC formed in the second region R2 may contact the second outermost side surface of the left molding member LMB and may contact the second outermost side surface of the right molding member RMB. The encapsulant EC may be formed so that a first height H1 in the first region R1 is greater than a second height H2 in the second region R2. For example, when it comes to a vertical level of the uppermost surface of the encapsulant EC, a first level in the first region R1 may be greater than a second level in the second region R2.

In some embodiments, the sidewall of each of the pair of first semiconductor chips 110R and 110L and the sidewall of each molding member MB may be coplanar, and the encapsulant EC may have a round (e.g., a concave) upper surface in the first region R1 and an inclined sidewall in the second region R2. The inclined side wall of the encapsulant EC in the second region R2 may have a straight, planar shape.

In some embodiments, the vertical level of the uppermost surface of the molding member MB is substantially the same as the vertical level of the uppermost surface of the pair of second semiconductor chips 120R and 120L, and the vertical level of the uppermost surface of the molding member MB may be higher than the vertical level of the uppermost surface of the encapsulant EC. For example, the uppermost surface of the molding member MB may be coplanar with the uppermost surface of the pair of second semiconductor chips 120R and 120L. The uppermost surface of the molding member MB may not be coplanar with the uppermost surface of the encapsulant EC.

When the semiconductor package 1 includes the molding member MB of the asymmetric shape, there may be an imbalance in volumes occupied by the molding member MB in the first region R1 and the second region R2. As such, unintentional stress such as warpage and/or twisting (hereinafter, collectively referred to as warpage) may occur in the semiconductor chips included in the semiconductor package 1. Moreover, because a thermal expansion coefficient of the material included in the molding member MB is relatively greater than the thermal expansion coefficient of the material included in the other components, a method for reducing the warpage in the semiconductor package 1 is necessary.

Therefore, in the semiconductor package 1 according to aspects of the inventive concept, the second left semiconductor chip 120L may have the left groove 120LG formed in a part of the base substrate 121 included therein, and the second right semiconductor chip 120R may have the right groove 120RG formed in a part of the base substrate 121 included therein. The left groove 120LG may be formed in the part of the base substrate 121 of the second left semiconductor chip 120L that is directly adjacent to the first region R1. The right groove 120RG may be formed in the part of the base substrate 121 of the second right semiconductor chip 120R that is directly adjacent to the first region R1.

In some embodiments, the pair of grooves 120RG and 120LG of the pair of second semiconductor chips 120R and 120L may be formed to have a mirror-image symmetry structure with each other based on (e.g., around) the first region R1. For example, the mirror-image symmetry may be symmetry around the first region R1 or around a central vertical axis extending through the first region R1. The left groove 120LG may be formed to cut parts of the uppermost surface of the second left semiconductor chip 120L and one sidewall adjacent to the first region R1. Also, the right groove 120RG may be formed to cut a part of the uppermost surface of the second right semiconductor chip 120R and a part of one sidewall adjacent to the first region R1.

Each of the pair of second semiconductor chips 120R and 120L may include a region (i.e., first portion) having a first thickness T1 and a region (i.e., second portion) having a second thickness T2 less than the first thickness T1. For example, vertical levels of the lower surfaces of the pair of grooves 120RG and 120LG may be lower than the vertical level of the uppermost surfaces of the pair of second semiconductor chips 120R and 120L. Also, a length of one sidewall in each of the pair of second semiconductor chips 120R and 120L, which is adjacent to the first region R1, in the vertical direction (Z-direction) may be less than the length of the other sidewall adjacent to the second region R2 in the vertical direction (Z-direction). The first thickness T1 may be equal to the maximum thickness of the base substrate 121. For example, no portion of the base substrate 121 has a thickness, measured in the vertical direction, greater than the first thickness T1. The second thickness T2 may be equal to the minimum thickness of the base substrate 121. For example, no portion of the base substrate 121 has a thickness, measured in the vertical direction, less than the second thickness T2. The top surface of the first portion having the first thickness T1 and the top surface of the second portion having the second thickness T2 are substantially planar.

With respect to the second left semiconductor chip 120L, the left groove 120LG may extend from a first side surface of the first portion (i.e., the first outermost side surface of the second left semiconductor chip 120L) to a first side surface of the second portion. The left groove 120LG may be L-shaped or substantially L-shaped. The first side surface of the first portion may be directly adjacent to and face the first region R1. The first side surface of the first portion may contact the molding member MB. The first side surface of the second portion may face the first region R1. The first side surface of the second portion may contact the molding member MB. A second side surface of the second portion (i.e., the second outermost side surface of the second left semiconductor chip 120L) may be directly adjacent to and face the second region R2. The second side surface of the second portion may contact the molding member MB.

With respect to the second right semiconductor chip 120R, the right groove 120RG may extend from a first side surface of the first portion (i.e., the first outermost side surface of the second right semiconductor chip 120R) to a first side surface of the second portion. The right groove 120RG may be reversed L-shaped or substantially reversed L-shaped. The first side surface of the first portion may be directly adjacent to and face the first region R1. The first side surface of the first portion may contact the molding member MB. The first side surface of the second portion may face the first region R1. The first side surface of the second portion may contact the molding member MB. A second side surface of the second portion (i.e., the second outermost side surface of the second right semiconductor chip 120R) may be directly adjacent to and face the second region R2. The second side surface of the second portion may contact the molding member MB.

In some embodiments, each of the pair of grooves 120RG and 120LG may be formed so that the sidewall and the lower surface in the groove meet each other at a round corner. The round corner may prevent the stress from concentrating on a part of the base substrate 121. In another embodiment, each of the pair of grooves 120RG and 120LG may be formed so that the sidewall and the lower surface in the groove may meet each other perpendicularly to each other.

According to the above shape, the molding member MB may be arranged to fill both of the pair of grooves 120RG and 120LG formed in the pair of second semiconductor chips 120R and 120L. Therefore, even when the semiconductor package 1 includes the molding member MB of asymmetric shape, imbalance in the volumes occupied by the molding member MB in the first region R1 and the second region R2 may be minimized by using the pair of grooves 120RG and 120LG, and thus, the warpage that may occur in the semiconductor package 1 may be effectively reduced.

Fundamentally, the semiconductor package 1 according to aspects of the inventive concept may effectively reduce a connection distance of the distribution for connecting signals between the pair of first semiconductor chips 110R and 110L while maintaining the protective reliability of the pair of first semiconductor chips 110R and 110L and the pair of second semiconductor chips 120R and 120L mounted on the package substrate 100, and also, may effectively reduce the warpage of the semiconductor chips included in the semiconductor package 1.

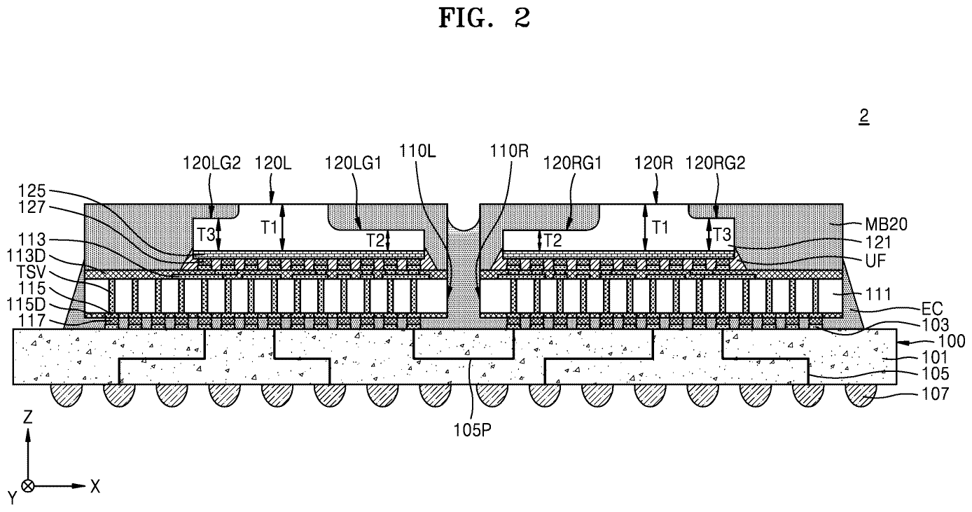

FIGS. 2 to 6 are cross-sectional views showing main components of a semiconductor package according to an embodiment.

Most of the elements forming the semiconductor packages 2, 3, 4, 5, and 6 and the materials included in the elements described below are substantially the same as or similar to the above descriptions provided with reference to FIG. 1. Therefore, for convenience of description, differences from the semiconductor package 1 described above are provided below.

Referring to FIG. 2, a semiconductor package 2 may include the package substrate 100, a pair of first semiconductor chips 110R and 110L, a pair of second semiconductor chips 120R and 120L, a molding member MB20, and the encapsulant EC.

In the semiconductor package 2 of the embodiment, the pair of second semiconductor chips 120R and 120L may have a pair of first grooves 120RG1 (e.g., “first right groove”) and 120LG1 (e.g., “first left groove”) in one side of the base substrate 121 included therein and a pair of second grooves 120RG2 (e.g., “second right groove”) and 120LG2 (e.g., “second left groove”) in the other side of the base substrate 121.

In detail, the second left semiconductor chip 120L may include the first left groove 120LG1 in one side of the base substrate 121 included therein, and the second left groove 120LG2 in the other side of the base substrate 121. Also, the second right semiconductor chip 120R may include the first right groove 120RG1 in one side of the base substrate 121 included therein, and the second right groove 120RG2 in the other side of the base substrate 121.

In some embodiments, the pair of second semiconductor chips 120R and 120L has the pair of first grooves 120RG1 and 120LG1 having a first depth to be adjacent to the first region where the second semiconductor chips 120R and 120L face each other, and has the pair of second grooves 120RG2 and 120LG2 having a second depth that is less than the first depth to be adjacent to the second region R2 where the second semiconductor chips 120R and 120L do not face each other. Additionally, a first width of each of the pair of first grooves 120RG1 and 120LG1 in the first horizontal direction (X-direction) may be greater than second width of each of the pair of second grooves 120RG2 and 120LG2 in the first horizontal direction (X-direction). For example, a first volume occupied by each of the pair of first grooves 120RG1 and 120LG1 may be greater than a second volume occupied by each of the pair of second grooves 120RG2 and 120LG2.

Each of the pair of second semiconductor chips 120R and 120L may include a region having a first thickness T1, a region having a second thickness T2 that is less than the first thickness T1, and a region having a third thickness T3 that is less than the first thickness T1 and greater than the second thickness T2. The region having the first thickness T1 may be disposed between the region having the second thickness T2 and the region having the third thickness T3.

In some embodiments, the pair of first grooves 120RG1 and 120LG1 may have a mirror-image symmetry structure with respect to each other based on the first region, and the pair of second grooves 120RG2 and 120LG2 may have a mirror-image symmetry structure with each other based on the first region.

In some embodiments, the pair of first grooves 120RG1 and 120LG1 formed in the pair of second semiconductor chips 120R and 120L may be arranged to overlap the pair of physical signal connection structures PHY (see FIG. 16) in the vertical direction (Z-direction). Unlike the above, the pair of second grooves 120RG2 and 120LG2 may be arranged so as not to overlap the pair of physical signal connection structures PHY (see FIG. 16) in the vertical direction (Z-direction).

The molding member MB20 may be arranged to fill all of the pair of first grooves 120RG1 and 120LG1 and the pair of second grooves 120RG2 and 120LG2 formed in the pair of second semiconductor chips 120R and 120L. Therefore, when the semiconductor package 2 includes the molding member MB20 of an asymmetric shape, the imbalance in the volumes occupied by the molding member MB20 in the first region R1 and the second region R2 is minimized by using the pair of first grooves 120RG1 and 120LG1, and thus, the warpage that may occur in the semiconductor package 2 may be effectively reduced.

Also, in the semiconductor package 2 of this embodiment, the pair of second grooves 120RG2 and 120LG2 are formed in the other sides of the pair of second semiconductor chips 120R and 120L, and thus, the upper surfaces of the pair of second semiconductor chips 120R and 120L may be variously modified and a strain concentration may be lessened. The first left groove 120LG1 may be formed in a part of the base substrate 121 of the second left semiconductor chip 120L that is directly adjacent to the first region R1. The first right groove 120RG1 may be formed in a part of the base substrate 121 of the second right semiconductor chip 120R that is directly adjacent to the first region R1. The second left groove 120LG2 may be formed in a part of the base substrate 121 of the second left semiconductor chip 120L that is directly adjacent to the second region R2. The second right groove 120RG2 may be formed in a part of the base substrate 121 of the second right semiconductor chip 120R that is directly adjacent to the second region R2.

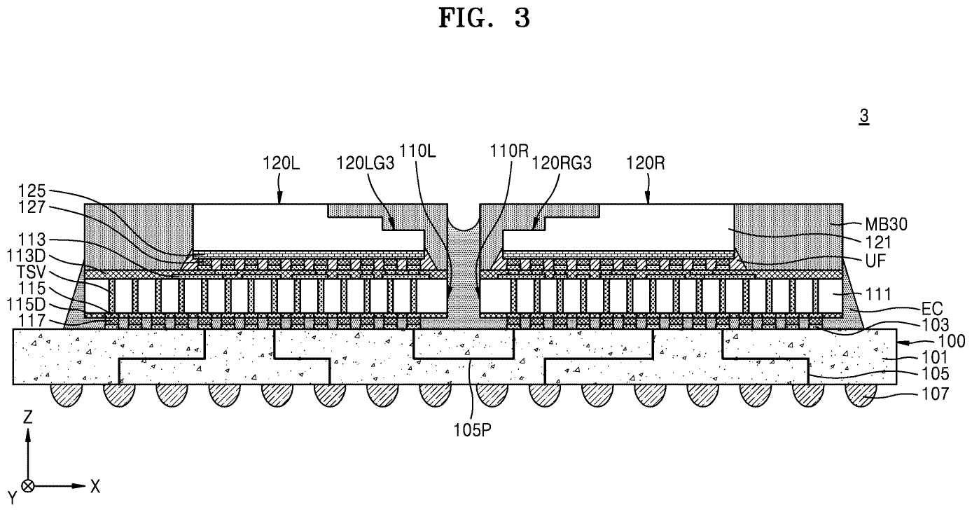

Referring to FIG. 3, a semiconductor package 3 may include the package substrate 100, a pair of first semiconductor chips 110R and 110L, a pair of second semiconductor chips 120R and 120L, a molding member MB30, and the encapsulant EC.

In the semiconductor package 3 of the embodiment, the pair of second semiconductor chips 120R and 120L may further include a pair of third grooves 120RG3 (i.e., “third right groove”) and 120LG3 (i.e., “third left groove”) in some parts of the base substrates 121 included therein.

In detail, the second left semiconductor chip 120L may have the third left groove 120LG3 having a stair-shape in a part of the base substrate 121 included therein, and the second right semiconductor chip 120R may have the third right groove 120RG3 having a stair-shape in a part of the base substrate 121 included therein. The third left groove 120LG3 may be formed in a part of the base substrate 121 of the second left semiconductor chip 120L that is directly adjacent to the first region R1. The third right groove 120RG3 may be formed in a part of the base substrate 121 of the second right semiconductor chip 120R that is directly adjacent to the first region R1.

In the pair of second semiconductor chips 120R and 120L in the semiconductor package 3 of the embodiment, each of the pair of third grooves 120RG3 and 120LG3 has a stair-shape including two steps, but is not limited thereto.

In some embodiments, the pair of third grooves 120RG3 and 120LG3 of the pair of second semiconductor chips 120R and 120L may be formed to a mirror-image symmetry structure with each other based on the first region R1 where the second semiconductor chips 120R and 120L face each other. Also, the molding member MB30 may be arranged to fill both the pair of third grooves 120RG3 and 120LG3 formed in the pair of second semiconductor chips 120R and 120L.

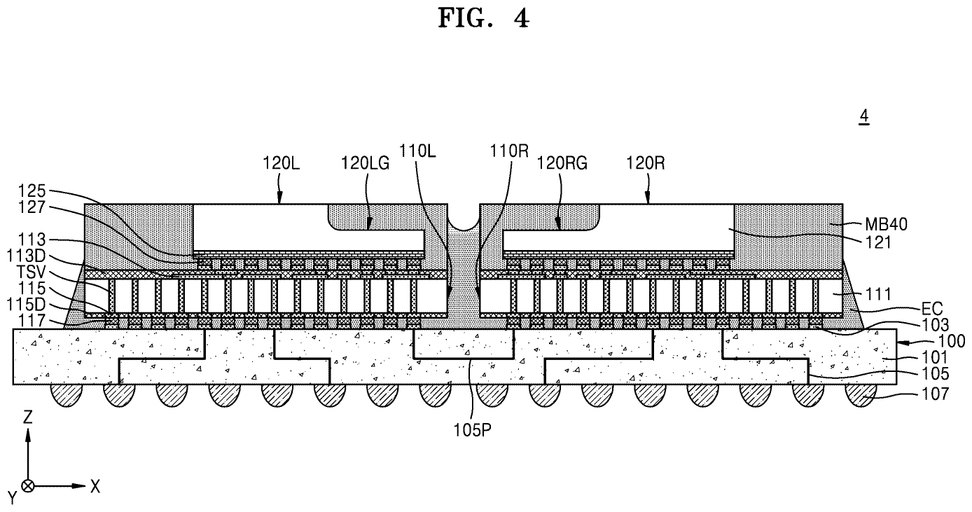

Referring to FIG. 4, a semiconductor package 4 may include the package substrate 100, a pair of first semiconductor chips 110R and 110L, a pair of second semiconductor chips 120R and 120L, a molding member MB40, and the encapsulant EC.

In the semiconductor package 4 of the embodiment, the underfill UF (see FIG. 1) is omitted, and the molding member MB40 may be formed by using a molded underfill (MUF) process. Accordingly, the molding member MB40 may be filled in the gaps between the pair of first semiconductor chips 110R and 110L and the pair of second semiconductor chips 120R and 120L. Also, the molding member MB40 may be arranged to fill both the pair of grooves 120RG and 120LG formed in the pair of second semiconductor chips 120R and 120L.

The molding member MB40 is formed by injecting an appropriate amount of molding material onto the package substrate 100 through an injection process and hardening the molding material. As necessary, the molding material is pressurized in a pressing process such as a press.

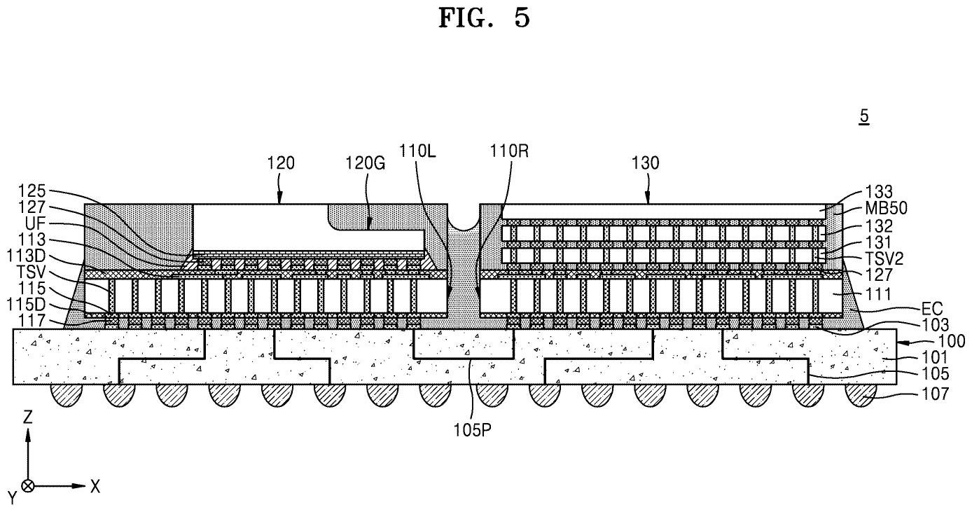

Referring to FIG. 5, the semiconductor package 5 includes the package substrate 100, the pair of first semiconductor chips 110R and 110L, a second semiconductor chip 120, a third semiconductor chip stack 130, a molding member MB50, and the encapsulant EC.

In the semiconductor package 5 of the embodiment, the second semiconductor chip 120 may be mounted on one of the pair of first semiconductor chips 110R and 110L. Also, the third semiconductor chip stack 130 may be mounted on the other of the pair of first semiconductor chips 110R and 110L. Here, the second semiconductor chip 120 may correspond to the second left semiconductor chip 120L (see FIG. 1).

In the semiconductor package 5 of the embodiment, the second semiconductor chip 120 is a system on chip and may include, for example, at least one processor such as an application processor (AP), a central processing unit (CPU), a graphic processing unit (GPU), etc., and a memory controller for controlling the third semiconductor chip stack 130. The second semiconductor chip 120 may receive/transmit signals from/to the third semiconductor chip stack 130 corresponding thereto via the memory controller.

The second semiconductor chip 120 may have a groove 120G in a part of the base substrate 121 included therein. Descriptions about the second semiconductor chip 120 and the groove 120G are substantially the same as the descriptions about the second left semiconductor chip 120L (see FIG. 1) and the left groove 120LG (see FIG. 1), and are omitted here.

In the semiconductor package 3 of the embodiment, the third semiconductor chip stack 130 is a stack-type memory chip, for example, and may be implemented based on a high bandwidth memory. However, the embodiment is not limited thereto, and the third semiconductor chip stack 130 may be implemented based on GDDR, HMC, or Wide I/O standard.

The third semiconductor chip stack 130 may have a stack structure including a first semiconductor die 131, a second semiconductor die 132, and a third semiconductor die 133, but the number of semiconductor dies included in the third semiconductor chip stack 130 is not limited to the example of the drawing.

In the third semiconductor chip stack 130, the first semiconductor die 131, the second semiconductor die 132, and the third semiconductor die 133 may be electrically connected to one another via a second through silicon via TSV2 and a second inner connection terminal 127, and may be electrically connected to the first right semiconductor chip 110R. In some embodiments, the third semiconductor die 133 arranged in the uppermost layer may not have the second through silicon via TSV2.

In the semiconductor package 5 of the embodiment, the third semiconductor chip stack 130 may not include any groove in the first semiconductor die 131, the second semiconductor die 132, and the third semiconductor die 133.

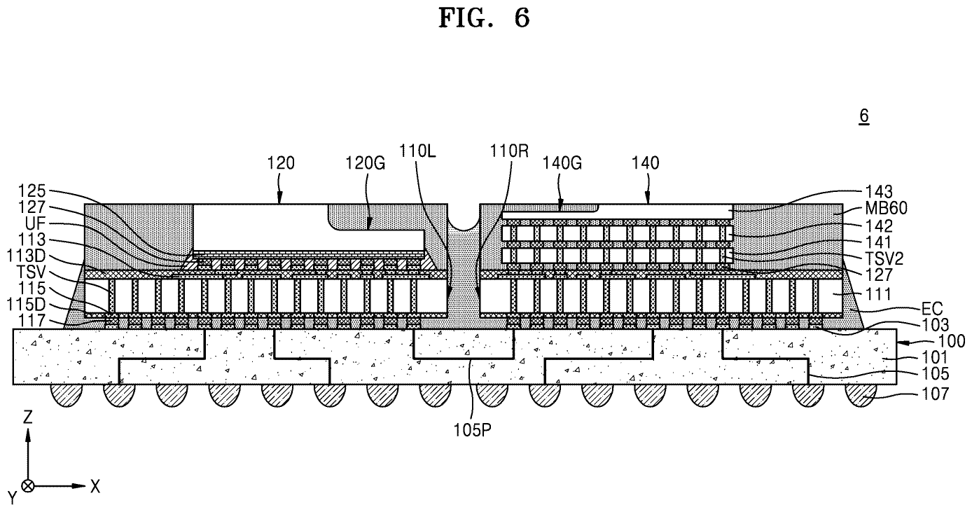

Referring to FIG. 6, the semiconductor package 6 includes the package substrate 100, the pair of first semiconductor chips 110R and 110L, a second semiconductor chip 120, a fourth semiconductor chip stack 140, a molding member MB60, and the encapsulant EC.

In the semiconductor package 6 of the embodiment, the second semiconductor chip 120 may be mounted on one of the pair of first semiconductor chips 110R and 110L. Also, the fourth semiconductor chip stack 140 may be mounted on the other of the pair of first semiconductor chips 110R and 110L. Here, the second semiconductor chip 120 may correspond to the second left semiconductor chip 120L (see FIG. 1).

In the semiconductor package 6 of the embodiment, the second semiconductor chip 120 is a system on chip and may include, for example, at least one processor such as AP, CPU, GPU, etc., and a memory controller for controlling the fourth semiconductor chip stack 140. The second semiconductor chip 120 may receive/transmit signals from/to the fourth semiconductor chip stack 140 corresponding thereto via the memory controller.

The second semiconductor chip 120 may have a groove 120G in a part of the base substrate 121 included therein. Descriptions about the second semiconductor chip 120 and the groove 120G are substantially the same as the descriptions about the second left semiconductor chip 120L (see FIG. 1) and the left groove 120LG (see FIG. 1), and are omitted here.

In the semiconductor package 6 of this embodiment, the fourth semiconductor chip stack 140 is a stack-type memory chip, for example, and may be implemented based on a high bandwidth memory. However, the embodiment is not limited thereto, and the fourth semiconductor chip stack 140 may be implemented based on graphics double data rate (GDDR), hybrid memory cube (HMC), or Wide I/O standard.

The fourth semiconductor chip stack 140 may have a stack structure including a first semiconductor die 141, a second semiconductor die 142, and a third semiconductor die 143, but the number of semiconductor dies included in the fourth semiconductor chip stack 140 is not limited to the example of the drawing.

In the fourth semiconductor chip stack 140, the first semiconductor die 141, the second semiconductor die 142, and the third semiconductor die 143 may be electrically connected to one another via a second through silicon via TSV2 and a second inner connection terminal 127, and may be electrically connected to the first right semiconductor chip 110R. In some embodiments, the third semiconductor die 143 arranged in the uppermost layer may not have the second through silicon via TSV2.

In the semiconductor package 6 of this embodiment, a fourth groove 140G may be formed in the third semiconductor die 143 arranged in the uppermost layer of the fourth semiconductor chip stack 140. In some embodiments, the fourth groove 140G may be formed to cut a part of the uppermost layer of the third semiconductor die 143 and a part of the sidewall of the third semiconductor die 143.

The groove 120G of the second semiconductor chip 120 and the fourth groove 140G of the fourth semiconductor chip stack 140 may be formed to face each other. The groove 120G of the second semiconductor chip 120 and the fourth groove 140G of the fourth semiconductor chip stack 140 may be directly adjacent to the first region R1. The groove 120G of the second semiconductor chip 120 may have a depth that is greater than that of the fourth groove 140G of the fourth semiconductor chip stack 140. Also, the molding member MB60 may be arranged to fill both the groove 120G of the second semiconductor chip 120 and the fourth groove 140G of the fourth semiconductor chip stack 140.

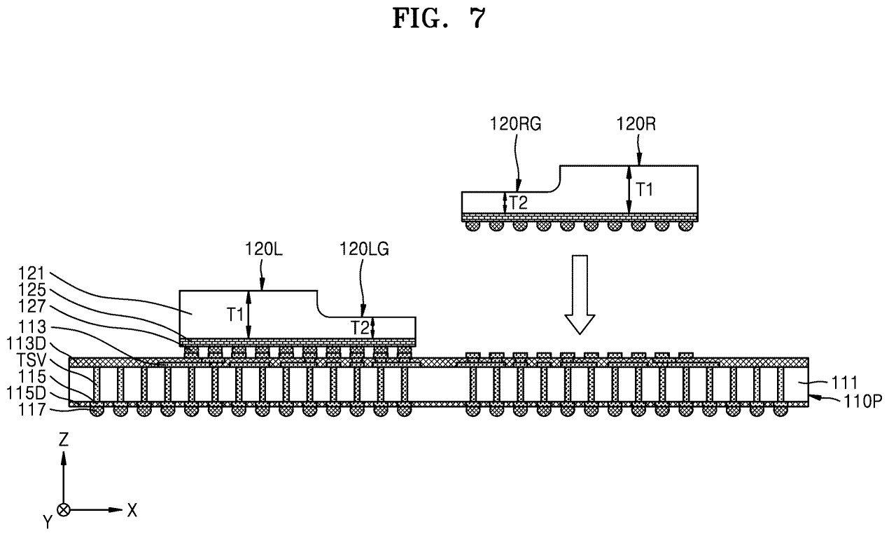

FIGS. 7 to 14 are cross-sectional views for illustrating a method of manufacturing a semiconductor package, according to an embodiment.

Referring to FIG. 7, a first semiconductor panel 110P may be prepared.

The first semiconductor panel 110P may include the base substrate 111, and an upper redistribution layer 113 formed on the upper surface of the base substrate 111 and a lower redistribution layer 115 formed on the lower surface of the base substrate 111. An upper insulating layer 113D may be arranged around the upper redistribution layer 113, and a lower insulating layer 115D may be arranged around the lower redistribution layer 115. The first semiconductor panel 110P may include a first inner connection terminal 117 under the lower redistribution layer 115.

First, a second semiconductor chip 120L may be mounted on the first semiconductor panel 110P. The second left semiconductor chip 120L may be mounted to be close to the center portion of the first semiconductor panel 110P.

Next, a second right semiconductor chip 120R may be located above the first semiconductor panel 110P. The second right semiconductor chip 120R may be located to be close to the center portion of the first semiconductor panel 110P.

Here, the second left semiconductor chip 120L may have the left groove 120LG in a part of the base substrate 121 included therein, and the second right semiconductor chip 120R may have the right groove 120RG in a part of the base substrate 121 included therein. Each of the second left semiconductor chip 120L and the second right semiconductor chip 120R may include the first portion having the first thickness T1 and the second portion having the second thickness T2 that is less than the first thickness T1.

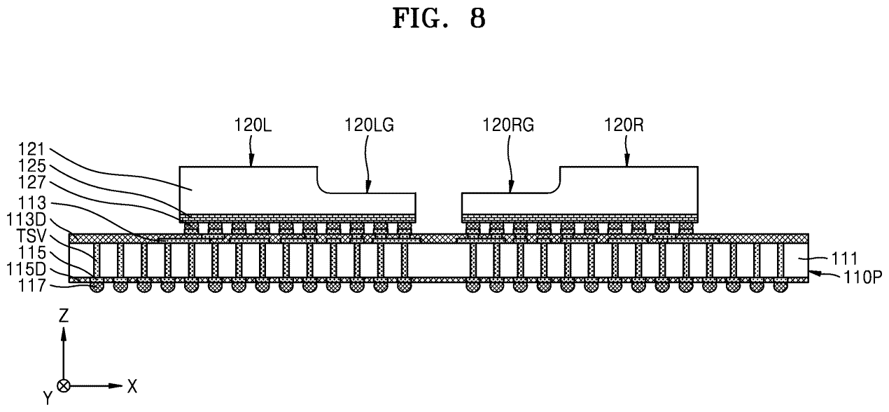

Referring to FIG. 8, the second right semiconductor chip 120R may be mounted on the first semiconductor panel 110P.

The second right semiconductor chip 120R may be mounted to be close to the center portion of the first semiconductor panel 110P. The first semiconductor panel 110P and the pair of second semiconductor chips 120R and 120L may be electrically and physically connected to each other via the second inner connection terminal 127.

Here, the left groove 120LG of the second left semiconductor chip 120L and the right groove 120RG of the second right semiconductor chip 120R may face each other.

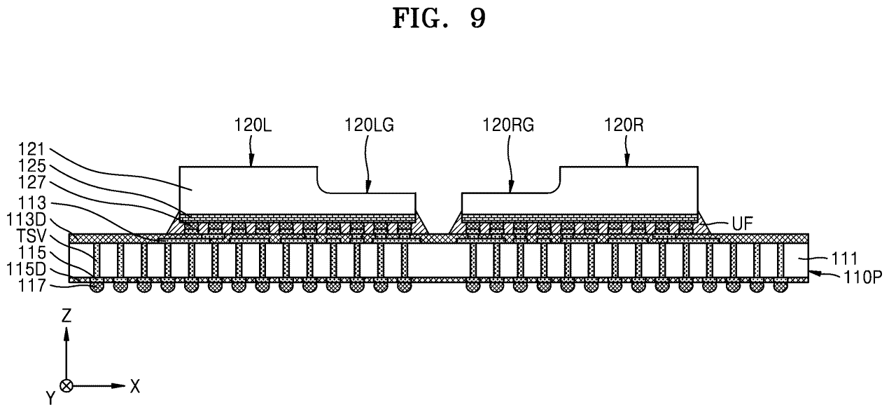

Referring to FIG. 9, the underfill UF may be injected between the first semiconductor panel 110P and each of the pair of second semiconductor chips 120R and 120L.

The underfill UF may be injected respectively into a region between the first semiconductor panel 110P and the second left semiconductor chip 120L and a region between the first semiconductor panel 110P and the second right semiconductor chip 120R. For example, in the electrical connection process of the second inner connection terminal 127, the underfill UF may be injected in order to secure the connection between the first semiconductor panel 110P and the pair of second semiconductor chips 120R and 120L.

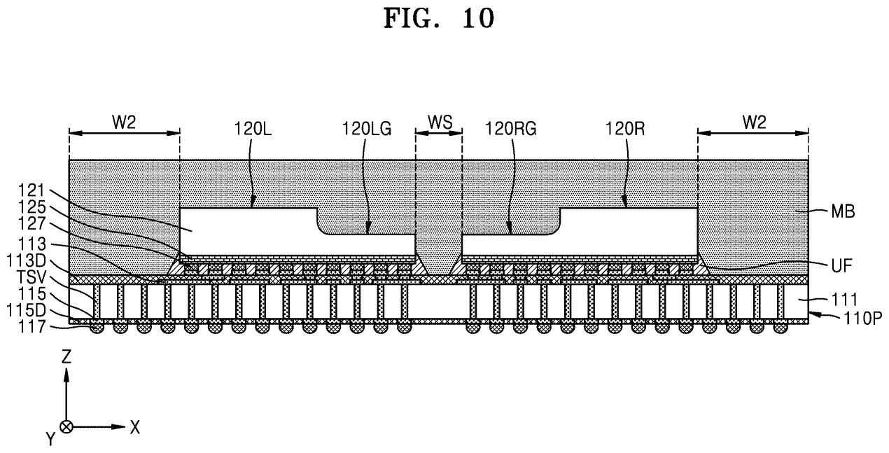

Referring to FIG. 10, the molding member MB may be formed to surround the pair of second semiconductor chips 120R and 120L and the underfill UF on the first semiconductor panel 110P.

According to aspects of the inventive concept, the molding member MB of an asymmetric shape (e.g., asymmetric overhang) may be formed on opposite sidewalls of each of the pair of second semiconductor chips 120R and 120L.

For example, the molding member MB may be formed to have a space width WS in the region between the pair of second semiconductor chips 120R and 120L, and a second width W2 that is greater than the space width WS in the peripheral region of the pair of second semiconductor chips 120R and 120L.

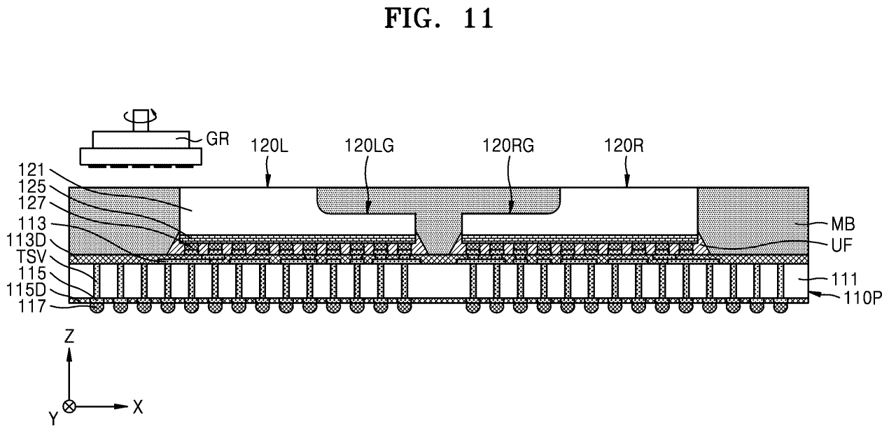

Referring to FIG. 11, the uppermost surfaces of the pair of second semiconductor chips 120R and 120L may be exposed by removing a part of the molding member MB.

A polishing and planarizing process is performed on the molding member MB by using a grinder GR. The polishing and planarizing process may be a chemical mechanical polishing process. The grinder GR may remove a part of the molding member MB through the polishing and planarizing process, and thus, a planarization layer exposing the uppermost layers of the pair of second semiconductor chips 120R and 120L may be formed.

Accordingly, the molding member MB may be formed to fill both the left groove 120LG of the second left semiconductor chip 120L and the right groove 120RG of the second right semiconductor chip 120R.

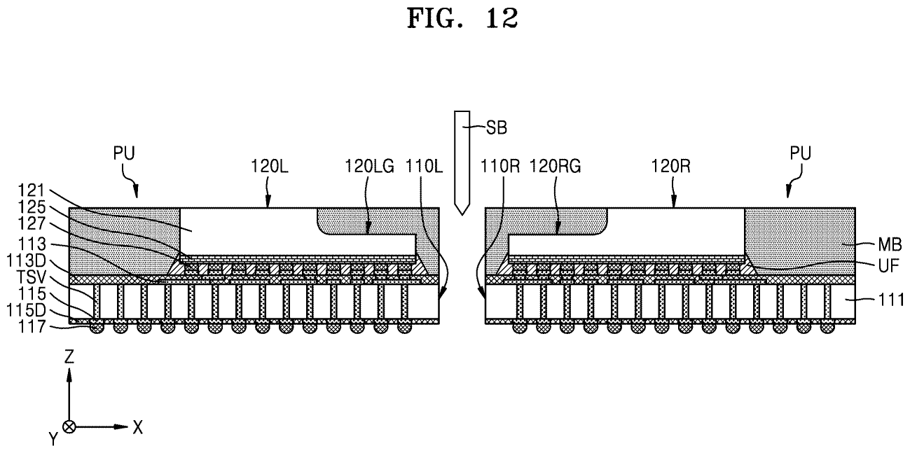

Referring to FIG. 12, the molding member MB and the first semiconductor panel 110P (see FIG. 11) are cut by using a sawing blade SB, and respective package units PU may be separated.

Accordingly, the pair of second semiconductor chips 120R and 120L may be mounted on the pair of first semiconductor chips 110R and 110L and may be physically separated. For example, the second left semiconductor chip 120L may be mounted on the first left semiconductor chip 110L to form a left package unit PU, and the second right semiconductor chip 120R may be mounted on the first right semiconductor chip 110R to form a right package unit PU.

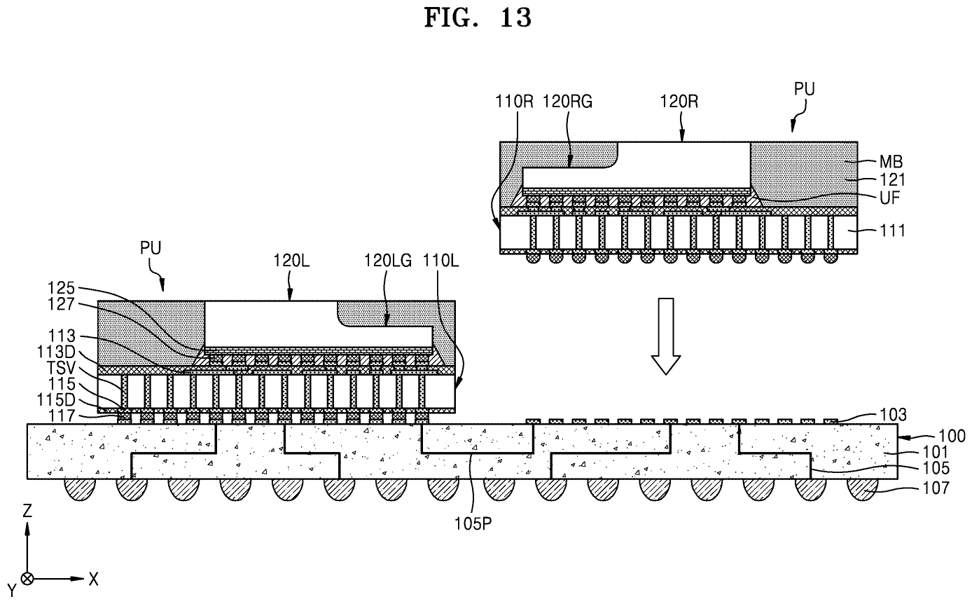

Referring to FIG. 13, the package substrate 100 may be prepared.

The package substrate 100 may include a lower electrode pad (not shown) in a body portion 101 and an upper electrode pad 103. Also, the package substrate 100 may include a wiring layer 105 in the body portion 101. An external connection terminal 107 may be arranged on the lower electrode pad on the lower surface of the package substrate 100.

First, the left package unit PU may be mounted on the package substrate 100. The left package unit PU may be mounted to be close to the center portion of the package substrate 100.

Next, the right package unit PU may be located above the package substrate 100. The right package unit PU may be located to be close to the center portion of the package substrate 100.

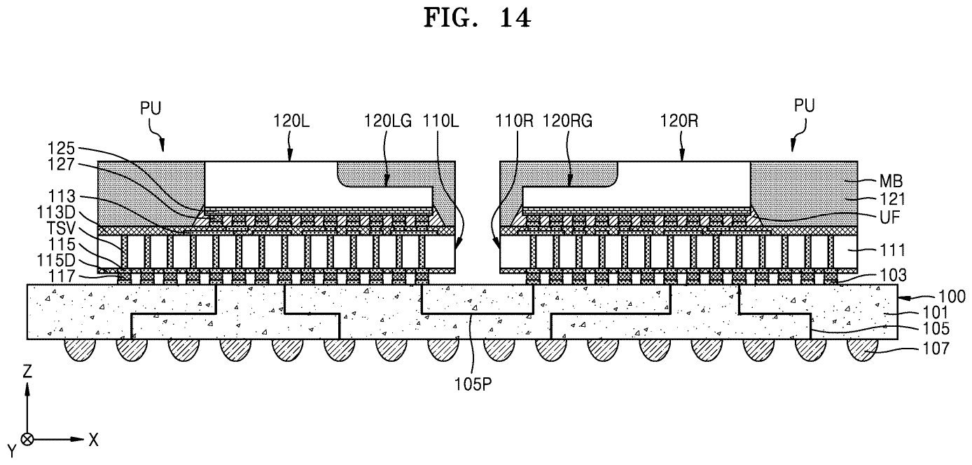

Referring to FIG. 14, the right package unit PU may be mounted on the package substrate 100.

The right package unit PU may be mounted to be close to the center portion of the package substrate 100. The package substrate 100 and the pair of package units PU may be electrically and physically connected to each other via a first inner connection terminal 117.

Here, the pair of second semiconductor chips 120R and 120L may have the pair of first grooves 120RG1 and 120LG1 having a first depth and formed adjacent to the first region where the second semiconductor chips 120R and 120L face each other, and the pair of first grooves 120RG1 and 120LG1 may be arranged to have a mirror-image symmetry structure with each other based on the first region.

Referring back to FIG. 1, the encapsulant EC may be formed to cover parts of the molding member MB surrounding the peripheries (e.g., sidewalls) of the pair of first semiconductor chips 110R and 110L and the pair of second semiconductor chips 120R and 120L on the package substrate 100.

Through the above manufacturing method, the semiconductor package 1 according to aspects of the inventive concept may be completed.

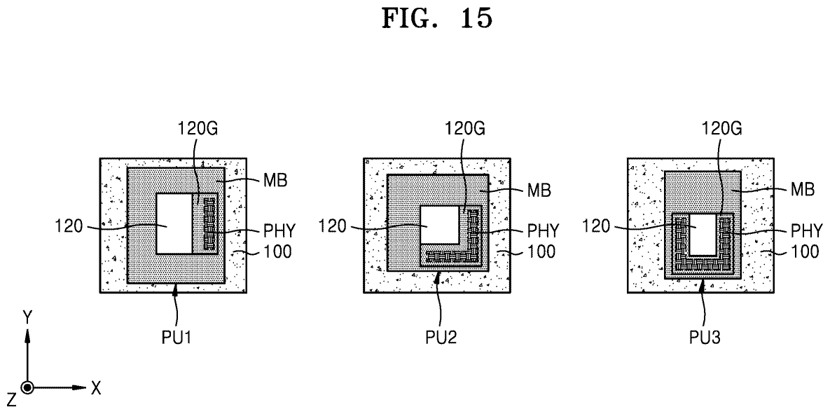

FIGS. 15 to 19 are plan views showing main components of a semiconductor package according to an embodiment.

Referring to FIG. 15, first to third package units PU1, PU2, and PU3 each including the second semiconductor chip 120 having the sides on which the molding member MB is asymmetrically arranged.

The second semiconductor chip 120 may refer to any one of the pair of second semiconductor chips 120R and 120L (see FIG. 1) described above. The second semiconductor chip 120 may include a groove 120G. The groove 120G may refer to a corresponding one of the pair of grooves 120RG and 120LG (see FIG. 1). Also, the second semiconductor chip 120 may include a physical signal connection structure PHY. The physical signal connection structure PHY is a part of the lower distribution layer 125 described above, and may refer to a structure performing a function of exchanging signals between neighboring second semiconductor chips 120.

Shortest distances from four sides (upper side, lower side, left side, right side) of the second semiconductor chip 120 in the first horizontal direction (X-direction) and the second horizontal direction (Y-direction) to corresponding four sides of the molding member MB may have at least one different value for one side. For example, the molding member MB may be asymmetrically arranged with respect to the four sides of the second semiconductor chip 120. Also, in a region where the shortest distance from the side of the second semiconductor chip 120 to the corresponding side of the molding member MB is relatively small, the physical signal connection structure PHY may be arranged, and the groove 120G may be formed in the region overlapping the physical signal connection structure PHY in the vertical direction (Z-direction).

Each of the first to third package units PU1, PU2, and PU3 includes the first semiconductor chip (one of 110R and 110L, see FIG. 1), the second semiconductor chip 120, the underfill UF (see FIG. 1), the molding member MB, and the encapsulant EC (see FIG. 1). Also, each of the first to third package units PU1, PU2, and PU3 may be mounted on the package substrate 100. Here, for convenience of description, the arrangement of the second semiconductor chip 120 and the groove 120G are described below.

In the first package unit PU1, a width of the molding member MB contacting the outermost right side of the second semiconductor chip 120 is less than the widths of the molding member MB contacting the other sides (upper side, lower side, left side). Accordingly, in the first package unit PU1, the groove 120G and the physical signal connection structure PHY may be located to be biased toward the right side of the second semiconductor chip 120.

In the second package unit PU2, the widths of the molding member MB contacting the outermost lower side and the outermost right side of the second semiconductor chip 120 in the drawing are less than the widths of the molding member MB contacting the other sides (upper side, left side). Accordingly, in the second package unit PU2, the groove 120G and the physical signal connection structure PHY may be located to be biased toward the lower side and the right side of the second semiconductor chip 120.

In the third package unit PU3, the widths of the molding member MB contacting the outermost lower side, the outermost left side, and the outermost right side of the second semiconductor chip 120 in the drawing are less than the width of the molding member MB contacting the other side (upper side). Accordingly, in the third package unit PU3, the groove 120G and the physical signal connection structure PHY may be located to be biased toward the lower side, the left side, and the right side of the second semiconductor chip 120.

Referring to FIG. 16, a semiconductor package 10 may include a pair of first package units PU1 that are mounted on the package substrate 100 to face each other.

The semiconductor package 10 of the embodiment may be substantially the same as the semiconductor package 1 (see FIG. 1) described above. For example, FIG. 1 may be a cross-sectional view of the semiconductor package of FIG. 16 taken along the first horizontal direction (X-direction).

The semiconductor package 10 of these embodiments reduces the distance (e.g., in the horizontal direction) between the physical signal connection structures PHY transmitting/receiving signals between the second left semiconductor chip 120 and the second right semiconductor chip 120, and thus, the connection distance of the distribution for signal connection may be effectively reduced.

In the semiconductor package 10 of the embodiment, the molding member MB may be arranged to fill both the grooves 120G of the second semiconductor chips 120 included respectively in the pair of first package units PU1. Therefore, when the first package unit PU1 includes the molding member MB of the asymmetric shape, the imbalance in the volumes occupied by the molding member MB may be minimized by using the grooves 120G, and the warpage that may occur in the first package unit PU1 may be effectively reduced.

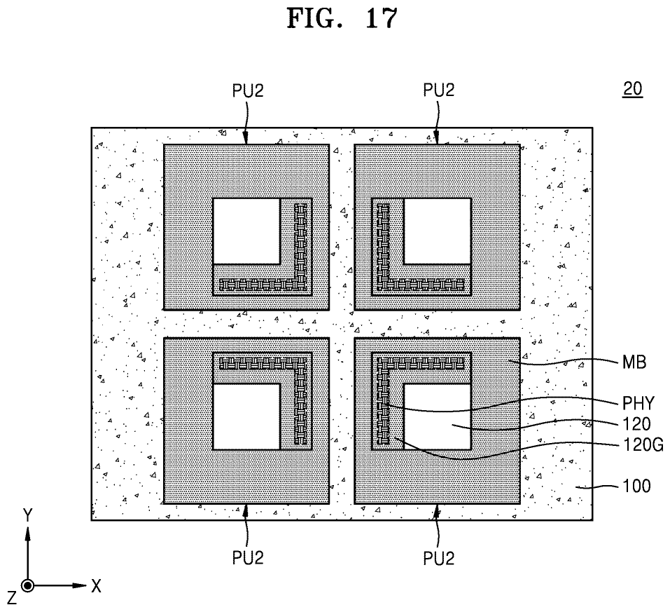

Referring to FIG. 17, a semiconductor package 20 may include four second package units PU2 that are mounted on the package substrate 100 to face one another.

The semiconductor package 20 of these embodiments may reduce the distance between the physical signal connection structures PHY transmitting/receiving the signals among the four second package units PU2, and thus, may effectively reduce the connection distance of the distribution for signal connection.

In the semiconductor package 20 of these embodiments, the molding member MB may be arranged to fill all of the grooves 120G of the second semiconductor chips 120 included respectively in the four second package units PU2. Therefore, when the second package unit PU2 includes the molding member MB of the asymmetric shape, the imbalance in the volumes occupied by the molding member MB may be minimized by using the grooves 120G, and the warpage that may occur in the second package unit PU2 may be effectively reduced.

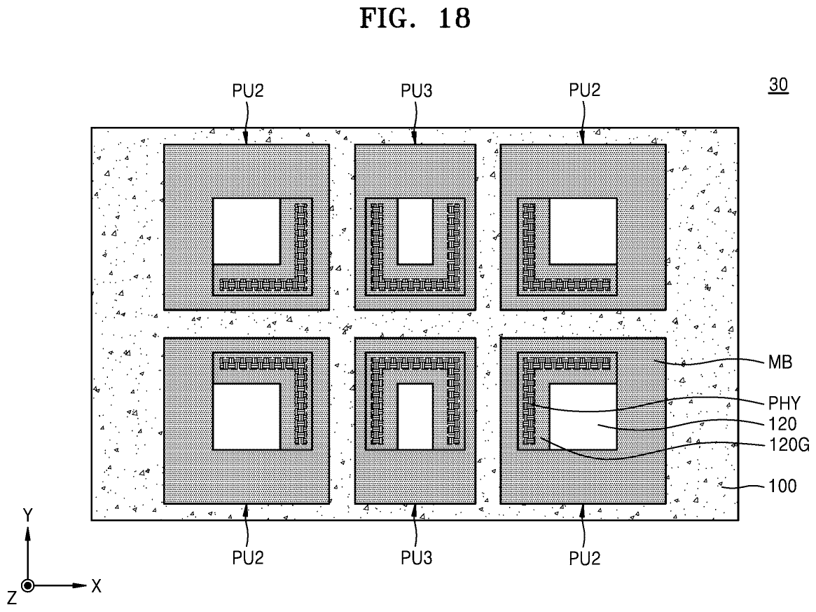

Referring to FIG. 18, a semiconductor package 30 may include four second package units PU2 and two third package units PU3 that are mounted on the package substrate 100 to face one another.

In the semiconductor package 30 of these embodiments, four second package units PU2 are arranged in mirror-image symmetry structure on the package substrate 100 with the two third package units PU3 therebetween, and thus mounted at positions where the distance between the respective physical signal connection structures PHY may be minimized.

The semiconductor package 30 of the embodiment reduces the distance between the physical signal connection structures PHY transmitting/receiving the signals between the four second package units PU2 and two third package units PU3, and thus may effectively reduce the connection distance of the distribution for signal connection.

In the semiconductor package 30 of these embodiments, the molding member MB may be arranged to fill all of the grooves 120G of the second semiconductor chips 120 included respectively in the four second package units PU2 and two third package units PU3. Therefore, even when the second package unit PU2 and the third package unit PU3 each have the molding member MB of the asymmetric shape, the imbalance in the volumes occupied by the molding member MB is minimized by using the grooves 120G, and thus, the warpage that may occur in each of the second package units PU2 and the third package units PU3 may be effectively reduced.

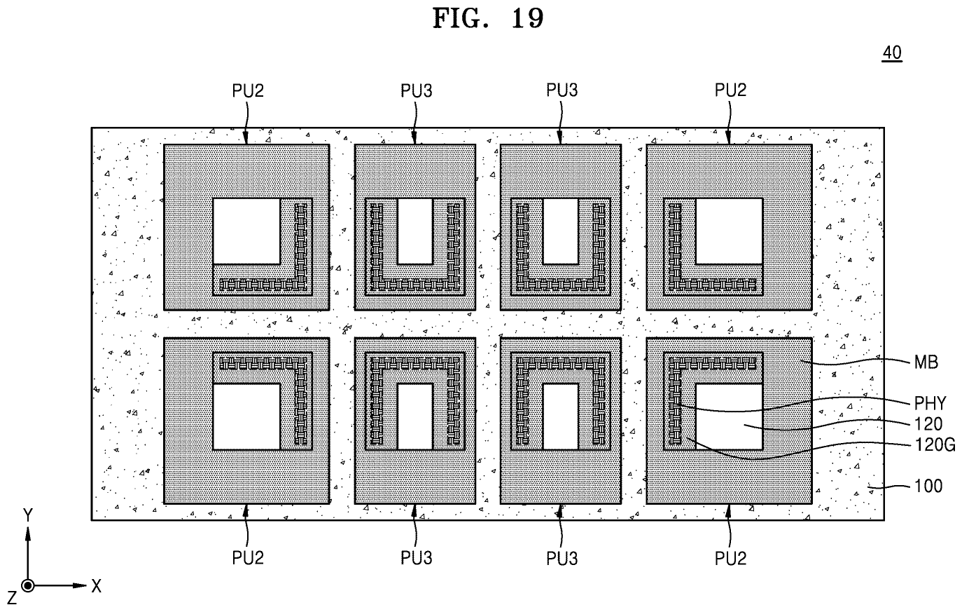

Referring to FIG. 19, a semiconductor package 40 may include four second package units PU2 and four third package units PU3 that are mounted on the package substrate 100 to face one another.

In the semiconductor package 40 of these embodiments, four second package units PU2 are arranged in mirror-image symmetry structure on the package substrate 100 with the four third package units PU3 therebetween, and thus mounted at positions where the distance between the respective physical signal connection structures PHY may be minimized.

The semiconductor package 40 of these embodiments reduces the distance between the physical signal connection structures PHY transmitting/receiving the signals between the four second package units PU2 and four third package units PU3, and thus may effectively reduce the connection distance of the distribution for signal connection.

In the semiconductor package 40 of these embodiments, the molding member MB may be arranged to fill all of the grooves 120G of the second semiconductor chips 120 included respectively in the four second package units PU2 and four third package units PU3. Therefore, even when the second package unit PU2 and the third package unit PU3 each have the molding member MB of the asymmetric shape, the imbalance in the volumes occupied by the molding member MB is minimized by using the grooves 120G, and thus, the warpage that may occur in each of the second package units PU2 and the third package units PU3 may be effectively reduced.

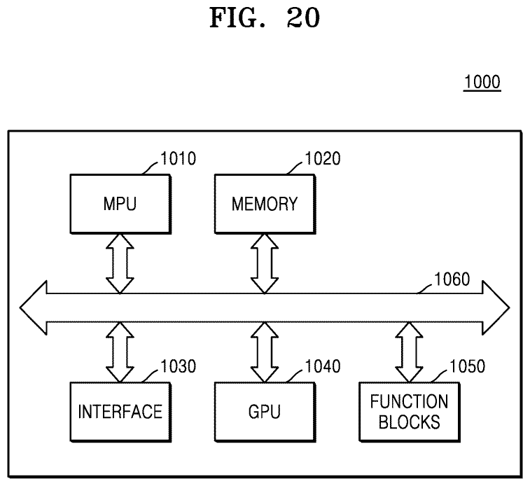

FIG. 20 is a block diagram schematically showing a semiconductor package according to some embodiments.

Referring to FIG. 20, the semiconductor package 1000 may include a micro-processor unit (MPC) 1010, a memory 1020, an interface 1030, a graphic-processor unit (GPU) 1040, functional blocks 1050, and a system bus 1060 connecting the above components.

The semiconductor package 1000 may include both the micro-processor unit 1010 and the GPU 1040, or may include only one of the micro-processor unit 1010 and the graphic processor unit 1040.

The micro-processor unit 1010 may include a core and a cache. For example, the micro-processor unit 1010 may include a multi-core. Cores in the multi-core may have the same or different performance. Also, the cores in the multi-core may be simultaneously activated or may be activated at different points in time.

The memory 1020 may store processing results in the functional blocks 1050, etc., according to the control from the micro-processor unit 1010. The interface 1030 may exchange information or signals with external devices. The graphic processor unit 1040 may perform graphic functions. For example, the GPU 1040 may execute a video codec or may process three-dimensional (3D) graphics. The functional blocks 1050 may perform various functions. For example, when the semiconductor package 1000 is an application processor used in a mobile device, some of the functional blocks 1050 may perform communication function.

The semiconductor package 1000 may include any one of the semiconductor packages 1, 2, 3, 4, 5, 6, 10, 20, 30, and 40 described above.

While aspects of the inventive concept have been particularly shown and described with reference to embodiments thereof, it will be understood that various changes in form and details may be made therein without departing from the spirit and scope of the following claims.

1. A semiconductor package comprising:
a package substrate;
a pair of first semiconductor chips mounted on the package substrate and facing each other in a first horizontal direction;
a pair of second semiconductor chips respectively mounted on the pair of first semiconductor chips and facing each other in the first horizontal direction;
a pair of molding members respectively disposed on the pair of first semiconductor chips, and covering peripheries of the pair of second semiconductor chips; and
an encapsulant on the package substrate, the encapsulant covering peripheries of the pair of first semiconductor chips and some parts of the pair of molding members,
wherein, in each of the pair of molding members, a first width in the horizontal direction in a first region where the pair of second semiconductor chips face each other is less than a second width in the horizontal direction in a second region where the pair of second semiconductor chips do not face each other, and
wherein a recess is formed in each of the pair of second semiconductor chips to a first depth in a direction in which the pair of second semiconductor chips face each other.

2. The semiconductor package of claim 1, wherein the recesses in the pair of second semiconductor chips have mirror-image symmetrical structures with respect to each other.

3. The semiconductor package of claim 2, wherein the pair of molding members fill the recesses in the pair of second semiconductor chips.

4. The semiconductor package of claim 1, wherein
the recesses comprise a cut part of an uppermost surface in each of the pair of second semiconductor chips and part of a first outermost side surface of each of the pair of second semiconductor chips, and
sidewalls and lower surfaces of the recesses meet each other at rounded corners.

5. The semiconductor package of claim 1, wherein
the recesses comprise a cut part of an uppermost surface in each of the pair of second semiconductor chips and part of a first outermost side surface of each of the pair of second semiconductor chips, and
the recesses have a stepped shape.

6. The semiconductor package of claim 1, wherein
a pair of physical signal connection structures configured to transmit and receive signals between the pair of second semiconductor chips are arranged adjacent to the first region, and
the recesses of the pair of second semiconductor chips overlap the pair of physical signal connection structures in a vertical direction.

7. The semiconductor package of claim 6, wherein the pair of physical signal connection structures are electrically connected to each other via the pair of first semiconductor chips and the package substrate.

8. The semiconductor package of claim 1, wherein
a sidewall of each of the pair of first semiconductor chips and an outermost surface of each of the molding members are coplanar with each other in a vertical direction,
in each of the pair of second semiconductor chips, a vertical length of a first outermost side surface adjacent to the first region is less than a vertical length of a second outermost side surface adjacent to the second region, and
the encapsulant has a round upper surface in the first region and has an inclined sidewall in the second region.

9. The semiconductor package of claim 8, wherein
uppermost surfaces of the pair of molding members is coplanar with the uppermost surfaces of the pair of second semiconductor chips,
a vertical level of lower surfaces of the recesses in the pair of second semiconductor chips is lower than a vertical level of uppermost surfaces of the pair of second semiconductor chips, and
the vertical level of the uppermost surfaces of the pair of molding members is higher than a vertical level of an uppermost surface of the encapsulant.

10. The semiconductor package of claim 1, wherein a width of each of the pair of second semiconductor chips in the horizontal direction is less than a width of each of the pair of first semiconductor chips in the horizontal direction.

11. A semiconductor package comprising:
a package substrate;
a pair of first semiconductor chips mounted on the package substrate and facing each other in a horizontal direction;
a pair of second semiconductor chips mounted on the pair of first semiconductor chips and facing each other in the horizontal direction;
a pair of molding members covering peripheries of the pair of second semiconductor chips on the pair of first semiconductor chips; and
an encapsulant covering peripheries of the pair of first semiconductor chips and some parts of the pair of molding members, on the package substrate,
wherein, in each of the pair of molding members, a first width in the horizontal direction in a first region where the pair of second semiconductor chips face each other is less than a second width in the horizontal direction in a second region where the pair of second semiconductor chips do not face each other,
a first recess of a first depth is formed in each of the pair of second semiconductor chips, adjacent to the first region, and
a second recess of a second depth that is less than the first depth is formed in each of the pair of second semiconductor chips, adjacent to the second region.

12. The semiconductor package of claim 11, wherein a first width of the first recess in the horizontal direction is greater than a second width of the second recess in the horizontal direction.

13. The semiconductor package of claim 12, wherein
the first recesses in the pair of second semiconductor chips have mirror-image symmetrical structures with respect to each other, and
the second recesses in the pair of second semiconductor chips have mirror-image symmetrical structures with respect to each other.

14. The semiconductor package of claim 11, wherein the pair of molding members fill the first recesses and the second recesses of the pair of second semiconductor chips.

15. The semiconductor package of claim 11, wherein
a pair of physical signal connection structures configured to transmit and receive signals between the pair of second semiconductor chips are arranged adjacent to the first region, and
in the pair of second semiconductor chips, the first recesses overlap the pair of physical signal connection structures in a vertical direction and the second recesses do not overlap the pair of physical signal connection structures in the vertical direction.

16. A semiconductor package comprising:
a package substrate;
a pair of first semiconductor chips mounted on the package substrate and facing each other in a horizontal direction;
a second semiconductor chip mounted on one of the pair of first semiconductor chips;
a semiconductor chip stack mounted on the other first semiconductor chip of the pair of first semiconductor chips;
a pair of molding members covering a periphery of the second semiconductor chip and a periphery of the semiconductor chip stack, on the pair of first semiconductor chips; and
an encapsulant covering peripheries of the pair of first semiconductor chips and some parts of the pair of molding members, on the package substrate,
the molding member arranged around the second semiconductor chip has a first width in the horizontal direction in a first region where the second semiconductor chip and the semiconductor chip stack face each other and a second width in the horizontal direction in a second region where the second semiconductor chip and the semiconductor chip stack do not face each other, the first width being less than the second width, and
a groove of a first depth is formed in the second semiconductor chip in a direction in which the second semiconductor chip and the semiconductor chip stack face each other.

17. The semiconductor package of claim 16, wherein
the groove is formed by cutting part of an uppermost surface in the second semiconductor chip and part of one sidewall of the second semiconductor chip, the sidewall being adjacent to the first region, and
a sidewall and a lower surface of the groove meet each other at a rounded corner.

18. The semiconductor package of claim 16, wherein
the semiconductor chip stack includes a stack structure of a plurality of semiconductor dies, and
the plurality of semiconductor dies are electrically connected to one another via a plurality of through silicon vias.

19. The semiconductor package of claim 18, wherein an uppermost layer groove is formed to a second depth in an uppermost semiconductor die from among the plurality of semiconductor dies.

20. The semiconductor package of claim 19, wherein the groove in the second semiconductor chip and the uppermost layer groove in the semiconductor chip stack face each other.

21-28. (canceled)
